(19) United States
(12) Patent Application Publication
(10) Pub. No.: US 2009/0130820 A1
(43) Pub. Date: May 21, 2009

(54) METHOD FOR MANUFACTURING A SEMICONDUCTOR DEVICE

(76) Inventor: Dae-Young Kim, Suwon-si (KR)

Correspondence Address: SHERR & VAUGHN, PLLC, 620 HERNDON PARKWAY, SUITE 200, HERNDON, VA, 20170, US

(21) Appl. No.: 12/263,525

(22) Filed: Nov. 3, 2008

(30) Foreign Application Priority Data
Nov. 16, 2007 (KR) 10-2007-0117573

(51) Int. Cl. H01L 21/762

(52) U.S. Cl. 438/433; 257/E21.546

(57) ABSTRACT

A method for manufacturing a semiconductor device includes forming a shallow trench isolation trench in a semiconductor substrate, and then forming a first oxide layer over the semiconductor substrate including the trench by exposing the semiconductor substrate including the shallow trench isolation trench to oxygen, and then implanting boron ions on the surface of the trench by performing an ion implantation on the STI trench process using BF₃ gas, and then removing the first oxide layer by exposing the first oxide layer to a buffered oxide etchant solution, and then forming a second oxide layer over the semiconductor substrate including the trench.

The present application claims priority under 35 U.S.C. §119 to Korean Patent Application No. 10-2007-0117573 (filed on Nov. 16, 2007), which is hereby incorporated by reference in its entirety.

### BACKGROUND

A plurality of unit cells such as transistors and capacitors are integrated in a limited area of a semiconductor device. For instance, thousands to billions of unit cells are integrated in the semiconductor device. Such cells are electrically separated or isolated from each other such that the cells can individually operate. In order to electrically isolate the cells from each other, a trench isolation process called “shallow trench isolation” (hereinafter, referred to as an STI), in which a trench is formed and then insulating material is filled in the trench, has been extensively used. In semiconductor devices such as an image sensor, a CMOS image sensor (CIS) is divided into a pixel area and a logic area, in which the pixel area is divided into a photodiode area and a transistor area. The photodiode area and the transistor area are separated from each other by an STI layer. Meanwhile, an STI ion implantation is performed on an STI area to enhance the isolation property.

However, the STI ion implantation process may cause damage to the STI area, in particular, to a corner of an STI trench, so electrical leakage occurs in the semiconductor device, in particular, in the CIS.

### SUMMARY

Embodiment relate to a method for manufacturing a semiconductor device that prevents defects due to electrical leakage in an STI area by minimizing damage to an inner surface of an STI trench during an ion implantation process for the STI trench.

Embodiments relate to a method for manufacturing the semiconductor device that may include at least one of the following: forming a shallow trench isolation (STI) trench in a semiconductor substrate, forming a buffer oxide layer on and/or over an entire surface of the semiconductor substrate including the STI trench, forming a photoresist pattern on and/or over the buffer oxide layer to expose the STI trench, performing an ion implantation on the STI trench using the photoresist pattern as a mask, removing the photoresist pattern and the buffer oxide layer, and then forming a liner oxide layer on and/or over the entire surface of the semiconductor substrate where the buffer oxide layer is removed.

Embodiments relate to a method that may include at least one of the following: forming a shallow trench isolation (STI) trench in a semiconductor substrate; and then forming a buffer oxide layer over an entire surface of the semiconductor substrate including the walls of the STI trench; and then forming a photoresist pattern over the buffer oxide layer to expose the STI trench; and then performing an ion implantation process on the STI trench using the photoresist pattern as a mask; and then removing the photoresist pattern and the buffer oxide layer; and then forming a liner oxide layer over the entire surface of the semiconductor substrate including the walls of the STI trench.

Embodiments relate to a method that may include at least one of the following: forming a trench in a semiconductor substrate; and then forming a first oxide layer over the semiconductor substrate including the trench; and then performing an ion implantation process on the STI trench; and then removing the first oxide layer; and then forming a second oxide layer over the semiconductor substrate including the trench.

Embodiments relate to a method that may include at least one of the following: forming a shallow trench isolation trench in a semiconductor substrate; and then forming a first oxide layer over the semiconductor substrate including the trench by exposing the semiconductor substrate including the shallow trench isolation trench to oxygen; and then implanting boron ions on the surface of the trench by performing an ion implantation on the STI trench process using BF₃ gas; and then removing the first oxide layer by exposing the first oxide layer to a buffered oxide etchant solution; and then forming a second oxide layer over the semiconductor substrate including the trench.

### DRAWINGS

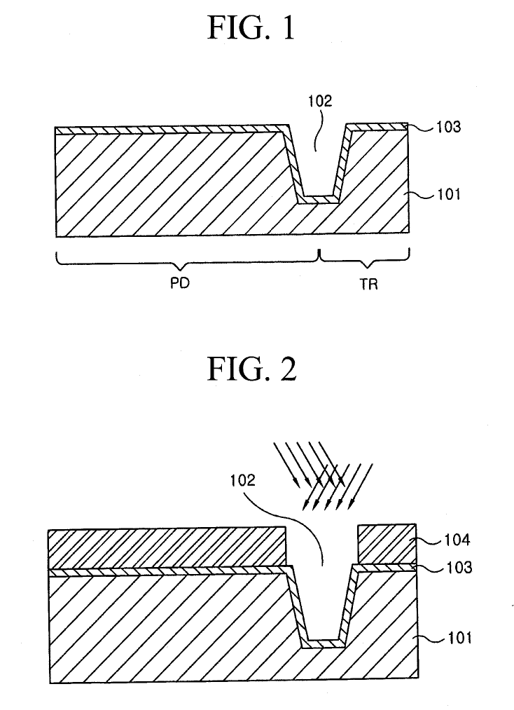

Example FIGS. 1 to 4 illustrate a method for manufacturing a semiconductor device in accordance with embodiments.

### DESCRIPTION

A method for manufacturing a semiconductor device in accordance with embodiments will be sequentially described with reference to example FIGS. 1 to 4. The method may include at least one of forming an STI trench, forming a buffer oxide layer, performing an STI ion implantation process, removing the buffer oxide layer and forming a liner oxide layer. The above steps will be described below in detail.

As illustrated in example FIG. 1, an STI trench 102 is formed in a semiconductor substrate 101 by forming a photoresist layer on and/or over the entire surface of the semiconductor substrate 101. A photoresist pattern is then formed by exposing a portion of the substrate 101 where STI trench 102 will be formed by subjecting the photoresist layer to an exposure and development process. Then, an etching process is performed using the photoresist pattern as an etching mask to form the STI trench 102 in the semiconductor substrate 101. In accordance with embodiments, a CIS (CMOS image sensor) may be employed as the semiconductor device in the method for manufacturing the semiconductor device. The STI trench 102 forms an STI structure for dividing a photodiode area PD from a transistor area TR in a pixel area separated from a logic area in the semiconductor substrate 101.

After the STI trench 102 has been formed in the semiconductor substrate 101, a buffer oxide layer 103 is formed on and/or over the entire surface of the semiconductor substrate 101 including the walls of the STI trench 102. The buffer oxide layer 103 is formed by exposing the surface of the semiconductor substrate 101 to oxygen (O₂) at a temperature in a range between approximately 800 to 1000° C., a flow rate in a range between approximately 400 to 800 sccm and a process time in a range between approximately 75 to 90 seconds. The buffer oxide layer 103 can be formed in a furnace or through a rapid thermal process (RTP). In accordance with embodiments, the buffer oxide layer 103 may have a thickness in a range between approximately 80 to 150 Å to prevent the STI trench 102 from being damaged in a subsequently occurring ion implantation process which will be described later.

As illustrated in example FIG. 2, after the buffer oxide layer 103 has been formed on and/or over the semiconductor substrate 101, a photoresist pattern 104 is formed on and/or over the buffer oxide layer 103 exposing only the STI trench 102. The photoresist pattern is formed by forming a photoresist on and/or over the buffer oxide layer 103 and then performing an exposure and development process on the photoresist. After the photoresist pattern 104 has been formed on and/or over the semiconductor substrate 101, an ion implantation process is performed on an inner surface of the STI trench 102 using the photoresist pattern 104 as a mask to maximize the isolation properties of the STI trench 102. The ion implantation is performed using BF₃ gas such that boron ions serving as impurity ions are implanted on sidewalls and the bottom wall of the STI trench 102. The ions are uniformly implanted on the sidewalls and bottom wall of the STI trench 102 by performing the ion implantation process with respect to the entire surface of the semiconductor substrate 101 at a tilted angle.

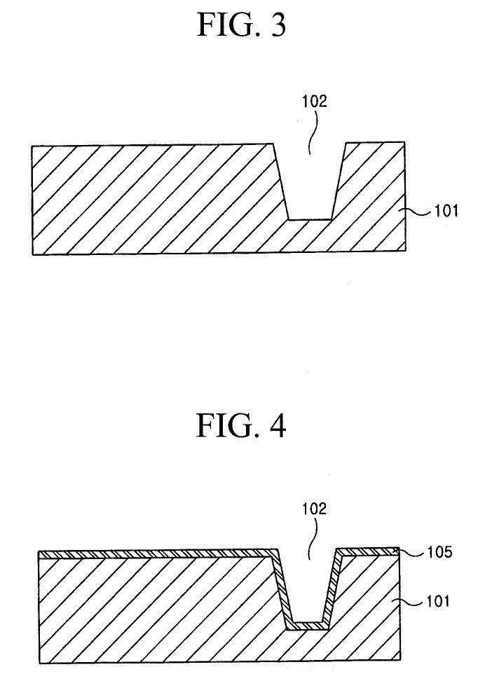

As illustrated in example FIG. 3, after the ion implantation process on the STI trench 102 has been completed, the photoresist pattern 104 and the buffer oxide layer 103 are removed. In accordance with embodiments, the photoresist pattern 104 may be removed through a strip process and the buffer oxide layer 103 may be removed by performing a cleaning process using a buffered oxide etchant (BOE) solution.

As illustrated in example FIG. 4, after the buffer oxide layer 103 has been removed, a gap fill of the STI trench 102 is performed to remove residual damage caused by the previously conducted ion implantation process in the STI area, by forming a liner oxide layer 105 on and/or over the entire surface of the semiconductor substrate 101 including the STI trench 102. The liner oxide layer 105 is formed by applying oxygen under the conditions of a temperature in a range between approximately 800 to 1000° C., a flow rate in a range between approximately 400 to 800 sccm and a process time in a range between approximately 75 to 90 seconds. The liner oxide layer 105 can be formed in a furnace or through an RTP process. In accordance with embodiments, the liner oxide layer 105 has a thickness in a range between approximately 80 to 150 Å.

In accordance with embodiments, the method for manufacturing a semiconductor device such as a CIS may include forming a buffer oxide layer 103 on and/or over the inner walls of the STI trench 102, which separates the photodiode area from the transistor area, before performing an ion implantation process. Such a method thereby maximizes the isolation properties of the STI trench 102. Therefore, damage to the inner surface of the STI trench 102 caused by the STI ion implantation is minimized, thereby preventing electrical leakage in the STI area. Accordingly, the reliability and product yield of the semiconductor device can be maximized.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a shallow trench isolation (STI) trench in a semiconductor substrate; and then
forming a buffer oxide layer over an entire surface of the semiconductor substrate including the walls of the STI trench; and then
forming a photoresist pattern over the buffer oxide layer to expose the STI trench; and then
performing an ion implantation process on the STI trench using the photoresist pattern as a mask; and then
removing the photoresist pattern and the buffer oxide layer; and then
forming a liner oxide layer over the entire surface of the semiconductor substrate including the walls of the STI trench.

2. The method of claim 1, wherein the STI trench separates a photodiode area from a transistor area in a CMOS image sensor.

3. The method of claim 1, wherein forming the buffer oxide layer comprises exposing the semiconductor substrate including the STI trench to oxygen at a predetermined temperature and a predetermined flow rate.

4. The method of claim 3, where the predetermined temperature is in a range between approximately 800 to 1000° C.

5. The method of claim 3, where the predetermined flow rate is in a range between approximately 400 to 800 sccm.

6. The method of claim 1, wherein the buffer oxide layer is formed at a thickness in a range between approximately 80 to 150 Å.

7. The method of claim 1, wherein removing the buffer oxide layer comprises performing a cleaning process using a buffered oxide etchant solution.

8. The method of claim 1, wherein forming the liner oxide layer comprises exposing the semiconductor substrate including the STI trench to oxygen at a predetermined temperature and a predetermined flow rate.

9. The method of claim 8, wherein the predetermined temperature is in a range between approximately 800 to 1000° C.

10. The method of claim 8, wherein the predetermined flow rate is in a range between approximately 400 to 800 sccm.

11. The method of claim 1, wherein the liner oxide layer is formed at a thickness in a range between approximately 80 to 150 Å.

12. A method comprising:
forming a trench in a semiconductor substrate; and then
forming a first oxide layer over the semiconductor substrate including the trench; and then
performing an ion implantation process on the STI trench; and then
removing the first oxide layer; and then
forming a second oxide layer over the semiconductor substrate including the trench.

13. The method of claim 12, wherein the trench comprises a shallow trench isolation trench.

14. The method of claim 1, wherein forming the first oxide layer comprises exposing the semiconductor substrate including the STI trench to oxygen at a first predetermined temperature and a first predetermined flow rate and forming the second oxide layer comprises exposing the semiconductor substrate including the STI trench to oxygen at a second predetermined temperature and a second predetermined flow rate.

15. The method of claim 14, wherein the first and second predetermined temperatures are in a range between approximately 800 to 1000° C.

16. The method of claim 14, wherein the first and second predetermined flow rates are in a range between approximately 400 to 800 sccm.

17. The method of claim 14, wherein the first oxide layer is formed at a thickness in a range between approximately 80 to 150 Å.

18. The method of claim 14, wherein removing the first oxide layer comprises exposing the first oxide layer to a buffered oxide etchant solution.

19. The method of claim 14, wherein the second oxide layer is formed at a thickness in a range between approximately 80 to 150 Å.

20. A method comprising:
forming a shallow trench isolation trench in a semiconductor substrate; and then
forming a first oxide layer over the semiconductor substrate including the trench by exposing the semiconductor substrate including the shallow trench isolation trench to oxygen; and then
implanting boron ions on the surface of the trench by performing an ion implantation on the STI trench process using BF₃ gas; and then
removing the first oxide layer by exposing the first oxide layer to a buffered oxide etchant solution; and then
forming a second oxide layer over the semiconductor substrate including the trench.
